(19) United States
(12) Patent Application Publication
(10) Pub. No.: US 2004/0206977 A1
(43) Pub. Date: Oct. 21, 2004

(54) Semiconductor light emitting diode and method for manufacturing the same

(75) Inventors: Jae-Hee Cho, Kyungki-do (KR); Hyun-Soo Kim, Kyungki-do (KR)

Correspondence Address: BURNS DOANE SWECKER & MATHIS L L P, POST OFFICE BOX 1404, ALEXANDRIA, VA, 22313-1404, US

(73) Assignee: SAMSUNG ELECTRONICS CO., LTD., Kyungki-do (KR)

(21) Appl. No.: 10/717,517

(22) Filed: Nov. 21, 2003

(30) Foreign Application Priority Data
Apr. 21, 2003 (KR) 2003-25084

(51) Int. Cl. H01L 31/0328

(52) U.S. Cl. 257/189

(57) ABSTRACT

A semiconductor light emitting diode. The semiconductor light emitting diode includes a substrate on which an n-type semiconductor layer, an active layer, and a p-type semiconductor layer are sequentially stacked, and a p-type electrode, which includes a first metallic layer formed on the p-type semiconductor layer and a second metallic layer that is formed on the first metallic layer and reflects light generated from the active layer.

### BACKGROUND OF THE INVENTION

This application claims the priority of Korean Patent Application No. 2003-25084, filed on Apr. 21, 2003, in the Korean Intellectual Property Office, the disclosure of which is incorporated herein in its entirety by reference.

1. Field of the Invention

The present invention relates to a semiconductor light emitting diode and a method for manufacturing the same, and more particularly, to a semiconductor light emitting diode in which a structure of a p-type electrode is changed to increase a light emitting amount, and a method for manufacturing the same.

2. Description of the Related Art

Semiconductor light emitting diodes are widely used as a means for data transmission in the field of communications, such as optical communications, or as a means for recording and reading data in an apparatus, such as a compact disc player (CDP) or a digital versatile disc player (DVDP). The semiconductor light emitting diodes have an extended range of applications, such as large-sized exterior electric signs or backlights for liquid crystal displays (LCDs).

FIG. 1 is a cross-sectional view schematically illustrating a structure of a conventional semiconductor light emitting diode. Referring to FIG. 1, an n-type semiconductor layer 2, an active layer 3 from which light is generated, and a p-type semiconductor layer 4 are sequentially formed on a top surface of a sapphire substrate 1. Reference numerals 5 and 6 respectively denote an n-type electrode electrically contacting the n-type semiconductor layer 2 and a p-type electrode electrically contacting the p-type semiconductor layer 4.

Light L1 generated from the active layer 3 is emitted to the outside via the n-type semiconductor layer 2 and the substrate 1. Light L2, having an emission angle greater than a critical angle calculated from a refractive index between the n-type semiconductor layer 2 and the substrate 1, is generated from the active layer 3, reflected at an interface between the n-type semiconductor layer 2 and the substrate 1, and emitted laterally while reflection is repeatedly performed between the p-type electrode 6 and the substrate 1. As this reflection is repeatedly performed, an energy of light is absorbed into the p-type electrode 6, and the intensity of light is rapidly reduced.

Thus, in order to improve light extraction efficiency of a semiconductor light emitting diode, a material having high light reflectivity, that is, a material having a low light absorption needs to be used for the p-type electrode 6. Also, the material for the p-type electrode 6 needs to make good ohmic contact with the p-type semiconductor layer 4.

When a metal, such as silver (Ag), having a low light absorption is bonded to the p-type semiconductor layer 4, an ohmic characteristic is bad because Ag has a high contact resistance with the p-type semiconductor layer 4. Thus, when Ag is used for the p-type electrode 6, a high driving voltage is needed to operate a semiconductor light emitting diode. In addition, Ag makes bad contact with a III-V nitride semiconductor layer widely used for the p-type semiconductor layer 2 and the n-type semiconductor layer 4.

In U.S. Pat. No. 6,486,499, a metallic material having high reflectivity, for example, silver (Ag), is used for a p-type electrode, and a contact area between the p-type electrode and a submount is increased, so as to improve an ohmic characteristic. In this case, the size of a semiconductor light emitting diode increases so that the number of semiconductor light emitting diodes that can be manufactured on each wafer is reduced.

### SUMMARY OF THE INVENTION

The present invention provides a semiconductor light emitting diode in which a p-type electrode having two metallic layers having complementary characteristics is used to improve light extraction efficiency, and a method for manufacturing the same.

According to an aspect of the present invention, a semiconductor light emitting diode includes a substrate on which an n-type semiconductor layer, an active layer, and a p-type semiconductor layer are sequentially stacked, and a p-type electrode, which includes a first metallic layer formed on the p-type semiconductor layer and a second metallic layer that is formed on the first metallic layer and reflects light generated from the active layer.

According to another aspect of the present invention, a method for manufacturing a semiconductor light emitting diode includes (a) sequentially stacking an n-type semiconductor layer, an active layer, and a p-type semiconductor layer on a substrate, and (b) forming a p-type electrode that electrically contacts the p-type semiconductor layer, on the p-type semiconductor layer. Step (b) includes sequentially stacking first metal and second metal on the p-type semiconductor layer and forming a first metallic layer that makes ohmic contact with the p-type semiconductor layer and a second metallic layer that reflects light.

The first metallic layer is formed of metal selected from palladium (Pd), platinum (Pt), and indium tin oxide (ITO), and the second metallic layer is formed of metal selected from silver (Ag) and aluminum (Al).

It is preferable that the thickness of the first metallic layer is between 1 nm and 10 nm inclusive and the thickness of the second metallic layer is more than 50 nm.

It is also preferable that the n-type semiconductor layer, the active layer, and the p-type semiconductor layer are GaN based III-V nitride compound and the active layer is an n-type material layer InₓAl_{y}Ga_{1″x″y}N (0≦x≦1, 0≦y≦1, and x+y≦1) based n-type material, or an undoped material layer.

### BRIEF DESCRIPTION OF THE DRAWINGS

The above and other aspects and advantages of the present invention will become more apparent by describing in detail preferred embodiments thereof with reference to the attached drawings in which:

FIG. 1 is a cross-sectional view schematically illustrating a structure of a conventional semiconductor light emitting diode;

FIG. 2 is a cross-sectional view illustrating a structure of a semiconductor light emitting diode according to an embodiment of the present invention;

FIG. 3 is a graph showing measurement results of a thermal processing characteristic of the semiconductor light emitting diode shown in FIG. 2, according to the present invention;

FIG. 4 is a graph showing measurement results of contact resistances of p-type electrodes shown in FIG. 2, according to the present invention;

FIG. 5 is a graph showing measurement results of light reflectivity of p-type electrodes shown in FIG. 2, according to the present invention;

FIG. 6 is a graph showing measurement results of output power of a semiconductor light emitting diode shown in FIG. 2, according to the present invention; and

FIG. 7 is a graph showing measurement results of flux of radiant light of a a semiconductor light emitting diode shown in FIG. 2, according to the present invention.

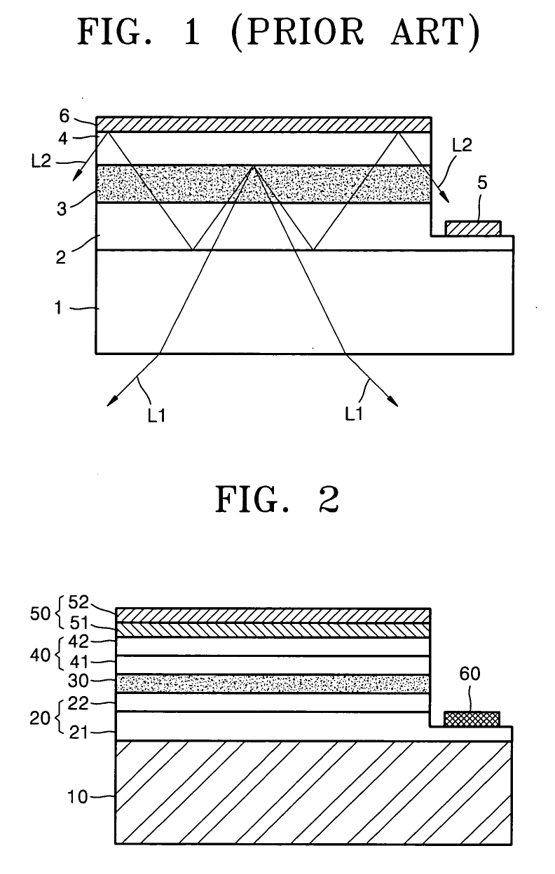

### DETAILED DESCRIPTION OF THE INVENTION

Hereinafter, preferred embodiments of the present invention will be described in detail, examples of which are illustrated in the accompanying drawings.

FIG. 2 is a cross-sectional view illustrating a structure of a semiconductor light emitting diode according to an embodiment of the present invention. Referring to FIG. 2, an n-type semiconductor layer 20, an active layer 30, and a p-type semiconductor layer 40 are sequentially stacked on a substrate 10.

The substrate 10 is a high resistance substrate. A sapphire substrate is mainly used for the substrate 10, and Si, SiC, or GaN substrate may also be used for the substrate 10.

The n-type semiconductor layer 20 includes a buffer layer 21 and a first cladding layer 22, which are sequentially formed on a top surface of the substrate 10. The p-type semiconductor layer 40 includes a second cladding layer 41 and a capping layer 42, which are sequentially formed on a top surface of the active layer 30.

The buffer layer 21 is an n-type material layer composed of a GaN based III-V nitride compound semiconductor, or an undoped material layer. Preferably, the buffer layer 21 is an n-GaN layer.

The capping layer 42 is a GaN based III-V nitride compound semiconductor layer. Preferably, the capping layer 42 is a direct transition-type GaN based III-V nitride compound semiconductor layer in which p-type conductive impurities are doped. More preferably, the capping layer 42 is a p-GaN layer. In addition, the capping layer 42 may be a GaN layer like the buffer layer 21, an AlGaN layer, or an InGaN layer in which aluminum (Al) or indium (In) is contained in a predetermined ratio.

Preferably, the first cladding layer 22 is an n-AlGaN/GaN layer. The second cladding layer 41 is the same material layer as the first cladding layer 22, except for having a p-type doping material.

The active layer 30 is a material layer in which light emission occurs due to recombination of carriers, such as electrons and holes. Preferably, the active layer 30 is a GaN based III-V nitride compound semiconductor layer having a multi-quantum well (MQW) structure. More preferably, the active layer 30 is an InₓAl_{y}Ga_{1″x″y}N (0≦x≦1, 0≦y≦1, and x+y≦1 ) layer. Besides, the active layer 30 may be a material layer in which indium (In) is contained with a GaN based III-V nitride compound semiconductor layer at a predetermined ratio, for example, an InGaN layer.

Although not shown, first and second waveguide layers are further stacked on and under the active layer 30 such that light emitted from the active layer 30 is amplified and oscillated as light having an increased light intensity. The first and second waveguide layers are formed of a material having a refractive index smaller than that of the active layer 30 and greater than those of the first and second cladding layers 22 and 41, preferably, for example, a GaN based III-V compound semiconductor layer. The first waveguide layer is formed of an n-GaN layer, and the second waveguide layer is formed of a p-GaN layer.

A p-type electrode 50 and an n-type electrode 60 are formed to electrically contact the p-type semiconductor layer 40 and the n-type semiconductor layer 20, respectively.

According to the above-described structure, electrons are implanted into the n-type semiconductor layer 20 via the n-type electrode 60, and holes are implanted into the p-type semiconductor layer 40 via the p-type electrode 50. The implanted electrons and holes meet in the active layer 30, become extinct, and make light having a short wavelength bandwidth oscillate. The color of emitted light varies according to a wavelength bandwidth. The wavelength bandwidth is determined by the width of an energy between a conduction band and a valence band formed by a material used for a semiconductor light emitting diode.

Light emitted from the active layer 30 is emitted to the outside via the n-type semiconductor layer 20 and the substrate 10. Light having an emission angle greater than a critical angle calculated from a refractive index between the n-type semiconductor layer 20 and the substrate 10, is generated from the active layer 30, reflected at an interface between the n-type semiconductor layer 20 and the substrate 10 and emitted laterally while reflection is repeatedly performed between the p-type electrode 50 and the substrate 10.

A first metal that has a low contact resistance with the p-type semiconductor layer 40 and makes good ohmic contact with the p-type semiconductor layer 40, and a second metal that does not reduce the intensity of light generated from the active layer 30 and has high light reflectivity are used together for the p-type electrode 50. As such, the p-type electrode 50 is used to supplement the disadvantage of each metal.

For this purpose, the p-type electrode 50 includes a first metallic layer 51 that makes good ohmic contact with the p-type semiconductor layer 40, and a second metallic layer 52 having high light reflectivity.

The first metal and the second metal are sequentially stacked on the capping layer 42, thereby forming the first and second metallic layers 51 and 52. The first metallic layer 51 makes ohmic contact with the capping layer 42. In order to reduce a driving voltage used to drive a semiconductor light emitting diode, preferably, the first metallic layer 51 is formed of metal having a contact resistance with the capping layer 42 as low as possible. In addition, preferably, the first metallic layer 51 is formed of metal having a contact resistance with the capping layer 42 lower than that of the second metal. The second metallic layer 52 reflects light generated from the active layer 30. Preferably, the second metallic layer is formed of a metal having light reflectivity higher than that of the first metal. Preferably, the first metal is one selected from the group consisting of palladium (Pd), indium tin oxide (ITO), and platinum (Pt). Preferably, the second metal is one selected from the group consisting of silver (Ag) and aluminum (Al).

In this way, it is preferable that the first and second metallic layers 51 and 52 are formed thermally-processed in an nonoxygen atmosphere and stabilized. After thermal processing, the first metallic layer 51 makes good ohmic contact with the capping layer 42, and the second metallic layer 52 becomes a solid solution.

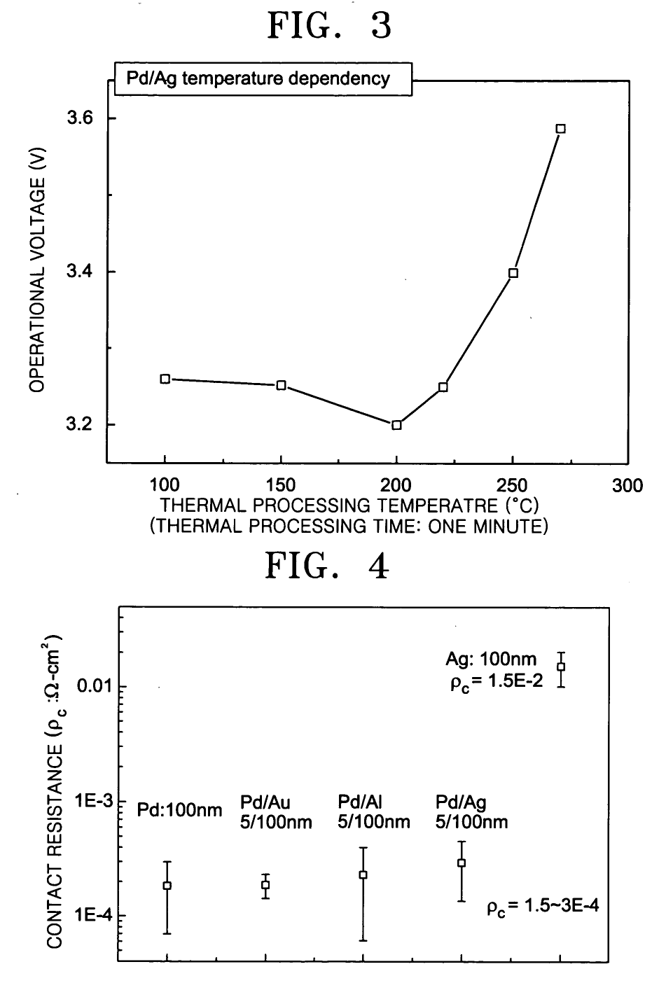

FIG. 3 is a graph showing measurement results of a thermal processing characteristic of the semiconductor light emitting diode shown in FIG. 2, according to the present invention. The graph shows a relation between a thermal processing temperature and an operational voltage of a semiconductor light emitting diode in a case where palladium (Pd) is used for the first metallic layer 51 of the p-type electrode 50 and silver (Ag) is used for the second metallic layer 52 of the p-type electrode 50. A thermal processing time is 1 minute, a supplying current is 20 mA, and an emission wavelength is 392 nm.

Referring to FIG. 3, when the thermal processing temperature is about 200° C., the operational voltage of the semiconductor light emitting diode is about 3.2 V. As the thermal processing temperature increases, the operational voltage increases. When the thermal processing temperature is about 280° C., the operational voltage of the semiconductor light emitting diode is about 3.6 V. Although not shown, preferably, a thermal processing temperature in the present embodiment is about between 80° C. and 350° C. inclusive. This is different from that a general thermal processing temperature required for good ohmic contact is more than 400° C.

The thickness of the first metallic layer 51 should be more than a minimum thickness in which the first metal retains the characteristic of metal. Preferably, the thickness of the first metallic layer 51 is between 1 nm and 10 nm inclusive. The thickness of the second metallic layer 52 should be in a range such that light does not transmit the second metallic layer 52. Preferably, the thickness of the second metallic layer 52 is more than 50 nm.

FIG. 4 is a graph showing measurement results of contact resistances of p-type electrodes shown in FIG. 2, according to the present invention. Pd:100 nm and Ag: 100 nm show contact resistances in a case where palladium (Pd) as a prior-art p-type electrode is stacked to a thickness of 100 nm (Pd: 100 nm) and in a case where silver (Ag) as a prior-art p-type electrode is stacked to a thickness of 100 nm (Ag: 100 nm). Pd/Au, Pd/Al, and Pd/Ag show contact resistances of the p-type electrodes 50 composed of the first metallic layer 51 in which palladium (Pd) is stacked to a thickness of 5 nm and the second metallic layer 52 in which silver (Ag), aluminum (Al), and gold (Au) are respectively stacked to a thickness of 100 nm, according to the present invention.

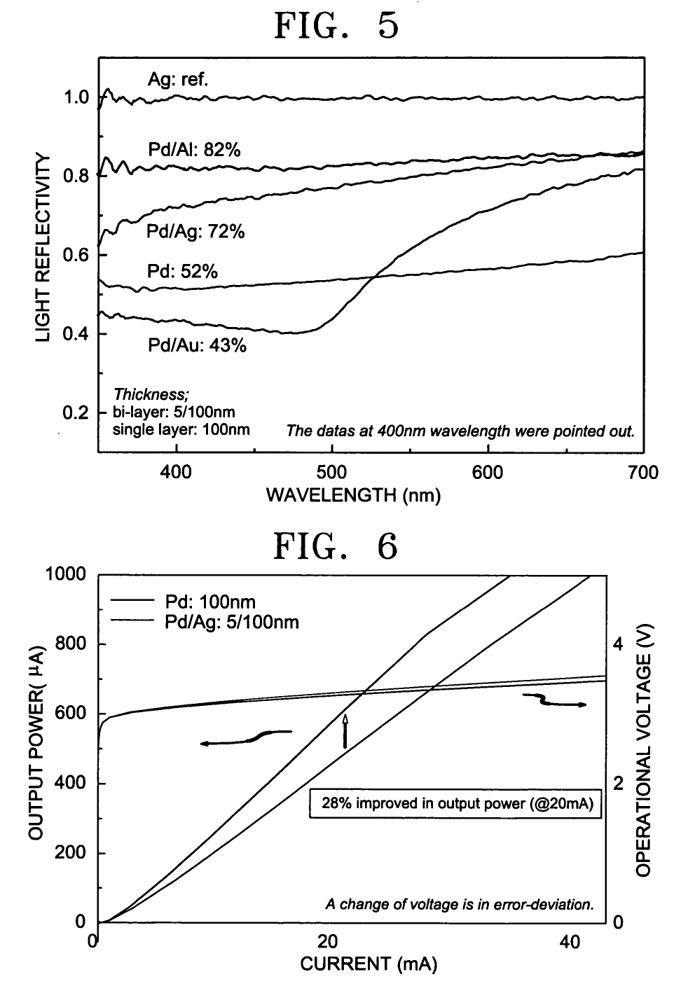

FIG. 5 is a graph showing measurement results of light reflectivity of p-type electrodes shown in FIG. 2, according to the present invention. Ag:ref shows a prior-art p-type electrode composed of a single layer formed of silver (Ag) having a thickness of 100 nm. Pd/Al, Pd/Ag, and Pd/Au show light reflectivity of the p-type electrodes 50 in which palladium (Pd) is stacked to a thickness of 5 nm and silver (Ag), aluminum (Al), and gold (Au) are respectively stacked to a thickness of 100 nm on palladium (Pd), according to the present invention. The graph shows relative light reflectivity of the p-type electrodes 50 according to the present invention when light reflectivity of the prior-art p-type electrode indicated by Ag:ref is 1. Percent numbers shown in the graph represent relative light reflectivity when an emission wavelength is 400 nm.

Referring to FIGS. 4 and 5, silver (Ag) has the highest light reflectivity but has the highest contact resistance with the p-type semiconductor layer 40, and does not make good ohmic contact with the p-type semiconductor layer 40. In addition, palladium (Pd) has the lowest contact resistance with the p-type semiconductor layer 40 and makes good ohmic contact with the p-type semiconductor layer 40. On the other hand, palladium (Pd) has light reflectivity of only 43% of light reflectivity of silver (Ag) and lowers light extraction efficiency. Thus, when only one of the above-described metal is used for the p-type electrode 50, a good ohmic characteristic and high light reflectivity cannot be simultaneously obtained.

However, the p-type electrode 50 according to the present invention includes the first metallic layer 51 formed of the first metal that makes good ohimc contact with the p-type semiconductor layer 40, and the second metallic layer 52 formed of the second metal having high light reflectivity, such that a good ohmic characteristic and high light reflectivity can be simultaneously obtained. Referring to FIGS. 4 and 5, a contact resistance of the p-type electrode 50 shown in a case where Pd/Au, Pd/Al, and Pd/Ag combinations are used for the p-type electrode 50, becomes almost similar to a contact resistance of the p-type electrode 50 shown in a case where only palladium (Pd) is used for the p-type electrode 50, and is greatly improved compared to a contact resistance of the p-type electrode 50 shown in a case where only silver (Ag) is used for the p-type electrode 50. In addition, when Pd/Ag and Pd/Al combinations are used for the p-type electrode 50, light reflectivity of the p-type electrodes 50 reaches 72% and 82% of light reflectivity of the p-type electrode 50 shown in a case where only silver (Ag) is used for the p-type electrode 50 and is greatly improved compared to light reflectivity 52% of the p-type electrode 50 shown in a case where only palladium (Pd) is used for the p-type electrode 50. Only, light reflectivity of the p-type electrode 50 shown in a case where a Pd/Au combination is used for the p-type electrode 50, is low in areas having a light wavelength of about 300-500 nm and high in areas having a light wavelength of about 500 nm.

FIG. 6 is a graph showing measurement results of output power of a semiconductor light emitting diode shown in FIG. 2, according to the present invention.

The graph shows an output power generated by a supplied current and an operational voltage in a case where palladium (Pd) as a prior-art p-type electrode is stacked to a thickness of 100 nm (Pd: 100 nm) and in a case where palladium (Pd) and silver (Ag) as the p-type electrode 50 are stacked to a thickness of 5 nm and 100 nm, respectively, according to the present invention (Pd/Ag: 5/100 nm). Here, output power is indicated by an output current value of an optical sensor in which light emitted from the semiconductor light emitting diode, is detected using the optical sensor. Thus, the output power shown in the graph does not have an absolute meaning but a relative meaning for comparison reasons.

Referring to FIG. 6, the operational voltage is almost similar. Thus, a contact resistance shown in a case where a Pd/Ag combination is used for the p-type electrode 50 is almost similar to a contact resistance shown in a case where only palladium (Pd) is used. In other words, the semiconductor light emitting diode can operate at a voltage lower than a voltage shown in a case where only silver (Ag) is used. Thus, like in U.S. Pat. No. 6,486,499, in order to reduce a contact resistance between a p-type electrode and a p-type semiconductor layer, a contact area between the p-type electrode and the p-type semiconductor layer needs not be increased.

In addition, when a supplied current is about 20 mA, an output power, shown in a case where a Pd/Ag combination is used for the p-type electrode 50, is about 28% improved compared to a case where only palladium (Pd) is used for the p-type electrode 50.

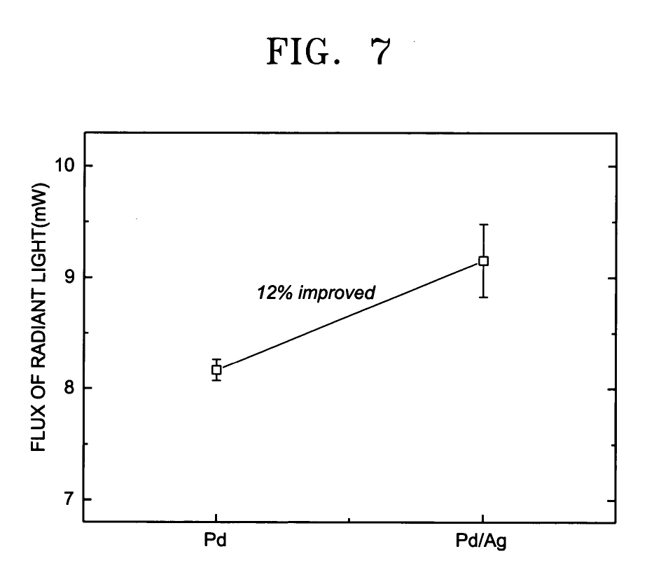

FIG. 7 is a graph showing measurement results of flux of radiant light of a semiconductor light emitting diode shown in FIG. 2, according to the present invention. The graph shows measurement results in a case where light having a wavelength of about 392 nm is emitted.

It can be seen from FIG. 7 that in a case where palladium (Pd) and silver (Ag) as the p-type electrode 50 are stacked to a thickness of 5 nm and 100 nm, respectively (Pd/Ag: 5/100 nm), flux of radiant light of the semiconductor light emitting diode is about 12% improved compared to a case where palladium (Pd) as a prior-art p-type electrode is stacked to a thickness of 100 nm (Pd: 100 nm).

As described above, in the semiconductor light emitting diode according to the present invention, a p-type electrode having a low contact resistance with a p-type semiconductor layer and simultaneously having a high light reflectivity is provided so that an operational voltage is reduced and light extraction efficiency is improved.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A semiconductor light emitting diode comprising:
a substrate on which an n-type semiconductor layer, an active layer, and a p-type semiconductor layer are sequentially stacked; and
a p-type electrode, which includes a first metallic layer formed on the p-type semiconductor layer and a second metallic layer that is formed on the first metallic layer and reflects light generated from the active layer.

2. The semiconductor light emitting diode of claim 1, wherein the first metallic layer has a contact resistance with the p-type semiconductor layer lower than that of the second metallic layer, and the second metallic layer has light reflectivity higher than that of the first metallic layer.

3. The semiconductor light emitting diode of claim 1, wherein the first metallic layer is formed of metal selected from palladium (Pd), platinum (Pt), and indium tin oxide (ITO).

4. The semiconductor light emitting diode of claim 3, wherein the thickness of the first metallic layer is between 1 nm and 10 nm inclusive.

5. The semiconductor light emitting diode of claim 1, wherein the second metallic layer is formed of metal selected from silver (Ag) and aluminum (Al).

6. The semiconductor light emitting diode of claim 5, wherein the thickness of the second metallic layer is more than 50 nm.

7. The semiconductor light emitting diode of claim 1, wherein the first and second metallic layers are thermally-processed in an nonoxygen atmosphere at a temperature between 80° C. and 350° C. inclusive.

8. The semiconductor light emitting diode of claim 1, wherein the n-type semiconductor layer, the active layer, and the p-type semiconductor layer are GaN based III-V nitride compound.

9. The semiconductor light emitting diode of claim 8, wherein the active layer is an n-type material layer InₓAl_{y}Ga_{1″x″y}N (0≦x≦1, 0≦y≦1, and x+y≦1) based n-type material, or an undoped material layer.

10. A method for manufacturing a semiconductor light emitting diode, the method comprising:
(a) sequentially stacking an n-type semiconductor layer, an active layer, and a p-type semiconductor layer on a substrate; and
(b) forming a p-type electrode that electrically contacts the p-type semiconductor layer, on the p-type semiconductor layer;
wherein step (b) includes sequentially stacking first metal and second metal on the p-type semiconductor layer and forming a first metallic layer that makes ohmic contact with the p-type semiconductor layer and a second metallic layer that reflects light.

11. The method of claim 10, wherein step (b) further includes thermally-processing the first and second metallic layers in an nonoxygen atmosphere at a temperature between 80° C. and 350° C. inclusive and stabilizing the first and second metallic layers.

12. The method of claim 10, wherein the first metal has a contact resistance with the p-type semiconductor layer lower than that of the second metal, and the second metal has light reflectivity higher than that of the first metal.

13. The method of claim 10, wherein the first metal is one selected from the group consisting of palladium (Pd), platinum (Pt), and indium tin oxide (ITO).

14. The method of claim 13, wherein the thickness of the first metallic layer is between 1 nm and 10 nm inclusive.

15. The method of claim 10, wherein the second metal is one selected from the group consisting of silver (Ag) and aluminum (Al).

16. The method of claim 15, wherein the thickness of the second metallic layer is more than 50 nm.

17. The method of claim 10, wherein the n-type semiconductor layer, the active layer, and the p-type semiconductor layer are GaN based III-V nitride compound.

18. The method of claim 17, wherein the active layer is an n-type material layer InₓAl_{y}Ga_{1″x″y}N (0≦x≦1, 0≦y≦1, and x+y≦1) based n-type material, or an undoped material layer.
